(19) United States
(12) Patent Application Publication
(10) Pub. No.: US 2018/0019349 A1
(43) Pub. Date: Jan. 18, 2018

(54) GRIDLESS PHOTOVOLTAIC CELLS AND METHODS OF PRODUCING A STRING USING THE SAME

(71) Applicant: SolarCity Corporation, San Mateo, CA (US)

(72) Inventor: Christoph G. Erben, Los Gatos, CA (US)

(73) Assignee: SolarCity Corporation, San Mateo, CA (US)

(21) Appl. No.: 15/209,307

(22) Filed: Jul. 13, 2016

(51) Int. Cl. H01L 31/02; H01L 31/0224; H01L 31/0376; H01L 31/20

(52) U.S. Cl. CPC H01L 31/0201; H01L 31/202; H01L 31/022433; H01L 31/03762

(57) ABSTRACT

One embodiment of the present invention provides a photovoltaic module. The photovoltaic module includes a front-side cover, a back-side cover, and a plurality of photovoltaic strings situated between the front- and back-side covers. A respective photovoltaic string includes a plurality of gridless photovoltaic cells sharing one or more metallic grids while coupled in series. The photovoltaic strings are in turn coupled in parallel to form the photovoltaic module.

### CROSS-REFERENCE TO OTHER APPLICATIONS

This is related to U.S. patent application Ser. No. 14/563,867, Attorney Docket Number P67-3NUS, entitled “HIGH EFFICIENCY SOLAR PANEL,” filed Dec. 8, 2014; and U.S. patent application Ser. No. 14/510,008, Attorney Docket No. P67-2NUS, entitled “MODULE FABRICATION OF SOLAR CELLS WITH LOW RESISTIVITY ELECTRODES,” filed 8 Oct. 2014, the disclosures of which are incorporated herein by reference in their entirety for all purposes.

This is also related to U.S. patent application Ser. No. 12/945,792, Attorney Docket No. P53-1NUS, entitled “Solar Cell with Oxide Tunneling Junctions,” filed 12 Nov. 2010; U.S. patent application Ser. No. 12/835,670, Attorney Docket No. P52-1NUS, entitled “Solar Cell with Metal Grid Fabricated by Electroplating,” filed 13 Jul. 2010; U.S. patent application Ser. No. 13/220,532, Attorney Docket No. P59-1NUS, entitled “Solar Cell with Electroplated Metal Grid,” filed 29 Aug. 2011, and U.S. patent application Ser. No. 13/048,804, Attorney Docket No. P54-1NUS, entitled “Solar Cell with a Shade-Free Front Electrode,” filed 15 Mar. 2011, the disclosure of which is incorporated herein by reference in its entirety herein for all purposes.

### FIELD OF THE INVENTION

This disclosure is related to solar panel design including fabrication of solar panels having gridless solar cells connected via a shared metallic grid.

### Definitions

A “photovoltaic structure,” refers to a device capable of converting light to electricity. A photovoltaic structure can include a number of semiconductors or other types of materials.

A “solar cell” or “cell” is a type of photovoltaic (PV) structure capable of converting light into electricity. A solar cell may have various sizes and shapes, and may be created from a variety of materials. A solar cell may be a PV structure fabricated on a semiconductor (e.g., silicon) wafer or substrate, or one or more thin films fabricated on a substrate (e.g., glass, plastic, metal, or any other material capable of supporting the photovoltaic structure).

A “finger line,” “finger electrode,” “finger strip,” or “finger” refers to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a PV structure for aggregating current collected by two or more finger lines. A busbar is usually wider than a finger line, and can deposited or otherwise positioned anywhere on or within the photovoltaic structure. A single photovoltaic structure may have one or more busbars.

A “metal grid,” “metallic gird,” or “grid” is typically a collection of finger lines and/or one or more busbars. The metal grid fabrication process typically includes depositing or otherwise positioning a layer of metallic material on the photovoltaic structure using various techniques.

A “solar cell strip,” “photovoltaic strip,” or “strip” is a portion or segment of a PV structure, such as a solar cell. A PV structure may be divided into a number of strips. A strip may have any shape and any size. The width and length of a strip may be the same or different from each other. Strips may be formed by further dividing a previously divided strip.

A “cascade” is a physical arrangement of adjacent solar cells or strips electrically coupled via electrodes at or near their edges. There are many ways to physically connect adjacent photovoltaic structures. One way would be physically overlapping them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

### BACKGROUND

The negative environmental impact of fossil fuels and their rising cost have resulted in need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi-junction structure includes multiple single-junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit. High efficiency solar cells are essential in reducing cost to produce solar energies.

In practice, multiple individual solar cells are interconnected, assembled, and packaged together to form a solar panel, which can be mounted onto a supporting structure. Multiple solar panels can then be linked together to form a solar system that generates solar power. Depending on its scale, such a solar system can be a residential roof-top system, a commercial roof-top system, or a ground-mount utility-scale system.

Note that in such systems, in addition to the energy conversion efficiency of each individual cell, the ways cells are electrically interconnected within a solar panel also determine the total amount of energy that can be extracted from each panel. Due to the conventional solar cell shape and inter-cell connections, a number of manufacturing steps are required in order to create and install the solar panels as a residential roof-top system, a commercial roof-top system, or a ground-mount utility-scale system. For example, conventional solar panels include solar cells each having metallic grid(s) that are connected to each other before being shipped to the installation site. It is desirable to provide an improved manufacturing and installation process of solar panels that is simpler, more cost effective, and reliable.

### SUMMARY

One embodiment provides a photovoltaic panel. The photovoltaic panel includes several photovoltaic cells arranged into multiple subsets, where some of the subsets include some pairs of gridless photovoltaic cells arranged to share one or more metallic grid(s). The photovoltaic cells in a subset can be electrically coupled in series, and the subsets of photovoltaic cells can be electrically coupled in parallel. The number of photovoltaic cells in a subset may be sufficiently large such that the output voltage of the photovoltaic panel is substantially the same as an output voltage of a conventional photovoltaic panel with all of its substantially square shaped photovoltaic cells coupled in series.

In some embodiments, the photovoltaic cell in a subset may be obtained by dividing a substantially square shaped photovoltaic cell.

In some embodiments, the photovoltaic cell in a subset may be obtained by dividing a substantially square shaped photovoltaic cell into three rectangular pieces.

In some embodiments, a respective photovoltaic cell may be a double-sided tunneling heterojunction photovoltaic cell, which includes a base layer, first and second quantum tunneling barrier (QTB) layers deposited on both surfaces of the base layer, an amorphous silicon emitter layer, and an amorphous silicon surface field layer. In addition, the photovoltaic cell can absorb light from both surfaces.

In some embodiments, the shared metallic grid can include intertwined metallic wires forming a mesh with openings that can be in shape of a square, rectangle, or trapezoid.

In some embodiments, the shared metallic grid can include interconnected metallic wires forming a mesh with openings that can be in shape of a square, rectangle, or trapezoid.

In some embodiments, the shared metallic grid can include at least one metallic wire forming an electrical connection between two adjacent photovoltaic cells, where the metallic wire can cover a portion of a photovoltaic surface and extend through another photovoltaic surface, thereby electrically connecting two adjacent photovoltaic cells.

In some embodiments, the metallic wire can be formed in shape of a serpentine with multiple parallel segments, where each end of the parallel segments is connected to one or more end portions of adjacent parallel sections.

In some embodiments, the shared metallic grid can include a busbar and some finger lines connected to the busbar, where the busbar may be coupled to at least one surface of each photovoltaic cell sharing the shared metallic grid.

In some embodiments, two adjacent photovoltaic cells in a subset are positioned such that the busbar may be connected to a first edge of a respective photovoltaic cell and a second edge of an adjacent photovoltaic cell partially overlapped on the first edge, thereby facilitating a serial connection between the two adjacent photovoltaic cells and eliminating uncovered space there between.

In some embodiments, the metallic grid may be coated with heat-activated and/or pressure-activated adhesive materials for bonding with one or more surfaces of photovoltaic cells sharing the metallic grid.

In some embodiments, the metallic grid may be coated with low melting conductive alloy for bonding with one or more surfaces of photovoltaic cells sharing the metallic grid.

In some embodiments, a photovoltaic panel fabrication process can include obtaining substantially square shaped fingerless photovoltaic cells, dividing each of the substantially square shaped fingerless photovoltaic cells into multiple smaller photovoltaic cells, electrically coupling a plurality of smaller photovoltaic cells to form a string using at least one shared metallic grid, electrically coupling multiple strings to form a photovoltaic panel, and applying a frond-side cover and a back side cover over the multiple electrically coupled strings.

In some embodiments, the photovoltaic cells in a respective subset can form a U-shaped string.

In some embodiments, the photovoltaic cells in the respective subset may be physically coupled.

### BRIEF DESCRIPTION OF THE FIGURES

FIG. 1 shows a detailed view of an exemplary gridless double-sided tunneling heterojunction photovoltaic cell.

FIG. 2 shows a detailed view of an exemplary electrode grid of a conventional photovoltaic cell.

FIG. 3A shows a detailed view of an exemplary metallic grid with a single edge busbar fabricated in isolation.

FIG. 3B shows a cross-sectional view of an exemplary metallic grid with a single edge busbar per surface attached to a fingerless bifacial photovoltaic cell.

FIG. 4A shows a cross-sectional view of an exemplary adhesive coated metallic grid attached to an exemplary fingerless bifacial photovoltaic cell.

FIG. 4B shows a cross-sectional view of an exemplary adhesive coated metallic grid with a substantially square shaped cross section attached to an exemplary fingerless bifacial photovoltaic cell.

FIG. 5A shows a detailed view of a shared metallic grid made from intertwined metallic wires.

FIG. 5B shows a detailed view of a shared metallic grid made from interconnected metallic wires.

FIG. 6 shows a detailed view of a serial connection of two adjacent photovoltaic structures sharing a single metallic grid formed from a network of metallic wires.

FIG. 7 shows a cross-sectional view of a string of gridless photovoltaic cells connected via shared metallic grids from a network of metallic wires.

FIG. 8 shows a detailed view of an exemplary photovoltaic panel having multiple photovoltaic strings connected in parallel with each photovoltaic string includes photovoltaic strips.

FIG. 9A shows a detailed view of an exemplary serial connection between two edge-overlapped adjacent photovoltaic cells with a shared metallic grid having a single edge busbar.

FIG. 9B shows a side view of an exemplary string of adjacent edge-overlapped photovoltaic cells with a shared metallic grid having a single edge busbar.

FIG. 10A shows a detailed view of an exemplary serial connection between adjacent photovoltaic cells with a shared metallic grid in form of a mesh.

FIG. 10B shows a side view of an exemplary string of adjacent edge-overlapped photovoltaic cells with a shared metallic grid in form of a mesh.

FIG. 11 shows a top view of an exemplary serial connection between two adjacent photovoltaic cells with a shared metallic grid having a serpentine pattern.

FIG. 12 shows a flow chart showing the process of fabricating a photovoltaic panel.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

Embodiments of the present invention provide highly efficient and improved interconnection scheme for PV modules by sharing metallic grids between PV cells. To increase efficiency, PV modules include a number of gridless photovoltaic cells sharing one or more metallic grids. As the result, the photovoltaic cells go through fewer fabrication operations as the electrodes are manufactured separately and fabricated easier in isolation. In addition, metallic grids are shared by adjacent PV cells, thereby decreasing the interconnection material used to fabricate electrodes, connect the PV cells together, and ultimately used for creating PV modules. Moreover, each conventional square-shaped wafer, after fabrication of the device structure, is divided into a number of cut cells, which can be rectangular-shaped strips and can be serially coupled to form photovoltaic panels with shared metallic grid having a higher degree of flexibility and adjustable packing density.

Because of greater freedom in choosing different metalization patterns while fabricating the metallic grid in isolation, several highly effective metalization patterns can be used instead of a traditional 2-busbar configuration, such as a single-busbar, free-form, and mesh configurations. In some embodiments, the shared metallic grid is bonded to adjacent PV cells using a coat of adhesive blend or a low-melting metal or alloy. To reduce shading and to increase the packing factor, in some embodiments, the cells are connected slightly overlapped in a shingled pattern.

### Gridless Bifacial Tunneling Junction Photovoltaic Cell

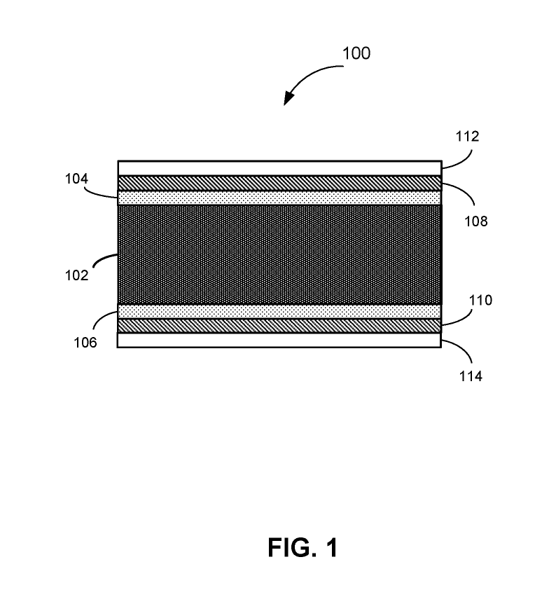

FIG. 1 shows an exemplary gridless double-sided tunneling junction photovoltaic structure, in accordance with an embodiment of the present invention. Unlike conventional photovoltaic structures, the exemplary double-sided photovoltaic structure does not include a metallic grid. Double-sided tunneling junction photovoltaic structure 100 includes substrate 102, quantum tunneling barrier (QTB) layers 104 and 106 covering opposite surfaces of substrate 102 and passivating the surface-defect states, a front-side doped a-Si layer forming front emitter 108, a back-side doped a-Si layer forming BSF layer 110, front transparent conducting oxide (TCO) layer 112, and back TCO layer 114. Note that it is also possible to have the emitter layer at the backside and a front surface field (FSF) layer at the front side of the PV structure. Details, including fabrication methods, about double-sided tunneling junction photovoltaic structure 100 can be found in U.S. patent application Ser. No. 12/945,792 (Attorney Docket No. P53-1NUS), entitled “Solar Cell with Oxide Tunneling Junctions,” by inventors Jiunn Benjamin Heng, Chentao Yu, Zheng Xu, and Jianming Fu, filed 12 Nov. 2010, the disclosure of which is incorporated herein by reference in its entirety herein.

As one can see from FIG. 1, the double-sided tunneling junction PV structure 100 ensures that it can be bifacial given that the backside is exposed to light. In photovoltaic structures, the metallic contacts, such as front and back metallic grids of a photovoltaic structure, can collect the current generated by the PV structure. In general, a metallic grid can include two types of metallic lines, including busbars and fingers. More specifically, busbars can be wider metallic lines that are connected directly to external leads (such as metal tabs), while fingers can be finer areas of metalization collecting current for delivery to the busbars. Since the photovoltaic structure 100 does not include any metallic contacts to collect current generated by the PV structure, metallic contacts are developed and fabricated separately and later affixed to the photovoltaic structure. Having the metallic contacts fabricated separately can have several advantages, namely, more efficient metallic grid patterns due to easier fabrication of metallic grids in isolation, such as electroplating, and also less fabrication processing on the photovoltaic structure.

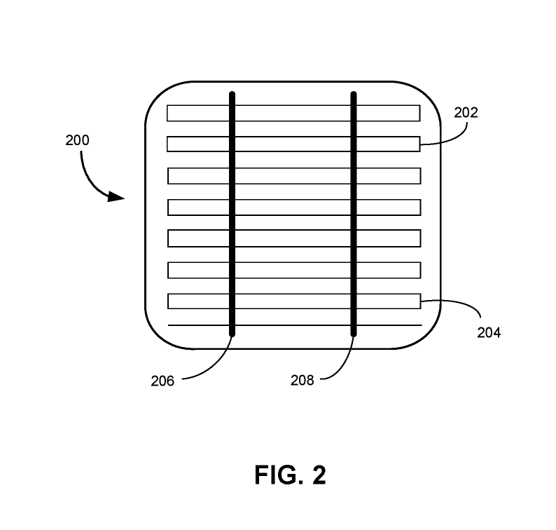

One factor in the metallic grid design is the balance between the increased resistive losses associated with a widely spaced grid and the increased reflection and shading effect caused by a high fraction of metallic coverage of the surface. In conventional PV structures, to prevent power loss due to series resistance of the finger lines, at least two busbars are placed on the surface of the photovoltaic cell to collect current from the fingers, as shown in FIG. 2.

For standardized PV structures, typically two or more busbars at each surface may be needed depending on the resistivity of the electrode materials. Note that in FIG. 2, a surface (which can be the front or back surface) of photovoltaic structure 200 includes a plurality of parallel finger lines, such as finger lines 202 and 204; and two busbars 206 and 208 placed substantially perpendicular to the finger lines. The busbars can be placed in such a way as to ensure that the distance (and hence the resistance) from any point on a finger to a busbar is small enough to minimize power loss. However, these two busbars and the metallic ribbons that are later soldered onto these busbars can create a significant amount of shading, which degrades the photovoltaic structure performance.

To further provide balance between the increased resistive losses associated with a widely spaced grid and the increased reflection and shading effect caused by a high fraction of metallic coverage of the surface. Therefore, by using an electroplating or electroless plating technique, which can be used easier and more reliably on the metallic grid in isolation, the reduced resistance of the Cu metallic grid makes it possible to have designs that maximize the overall efficiency of a photovoltaic structure by reducing or eliminating busbars on its surface. The power loss caused by the increased distance from the fingers to the busbar can be balanced by the reduced shading.

In some embodiments, the front and back metallic grids, such as the finger lines, can include electroplated Cu lines. By using an electroplating or electroless plating technique, one can obtain Cu grid lines with a resistivity of equal to or less than 5×10⁻⁶ Ω·cm. In general, a metal seed layer (such as Ti) can be deposited directly on the TCO layer using, for example, a physical vapor deposition (PVD) process to ensure proper ohmic contact with the TCO layer as well as a strong physical bond with the photovoltaic cell structure so that the Cu grid can be electroplated onto the seed layer. However, by having the metallic grid electroplated in isolation, the metal seed layer process can be eliminated while still ensuring excellent ohmic contact quality, physical strength, low cost, and facilitating large-scale manufacturing. Details about an electroplated Cu grid can be found in U.S. patent application Ser. No. 12/835,670 (Attorney Docket No. P52-1NUS), entitled “Solar Cell with Metal Grid Fabricated by Electroplating,” by inventors Jianming Fu, Zheng Xu, Chentao Yu, and Jiunn Benjamin Heng, filed 13 Jul. 2010; and U.S. patent application Ser. No. 13/220,532 (Attorney Docket No. P59-1NUS), entitled “Solar Cell with Electroplated Metal Grid,” by inventors Jianming Fu, Jiunn Benjamin Heng, Zheng Xu, and Chentao Yu, filed 29 Aug. 2011, the disclosures of which are incorporated herein by reference in their entirety herein.

The reduced resistance of the Cu fingers makes it possible to have a metallic grid design that maximizes the overall efficiency of a photovoltaic structure by reducing the number of busbars on its surface. The power loss caused by the increased distance from the fingers to the busbar can be balanced by the reduced shading.

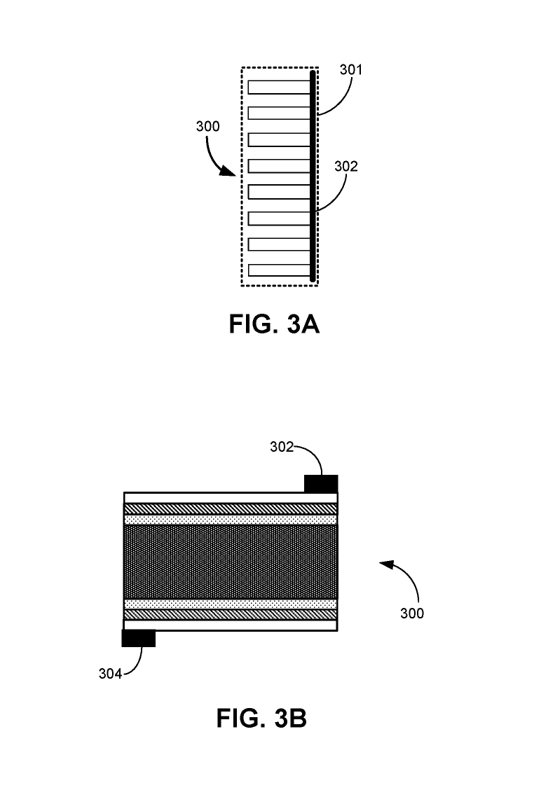

FIG. 3A shows an exemplary metallic grid fabricated in isolation and to be used with a photovoltaic structure. In FIG. 3A, the metallic grid 300 includes a number of horizontal finger lines and a vertical single busbar 302, which can be placed at an edge of a PV structure. More specifically, busbar 302 is in contact with the rightmost edge of all the finger lines, and collects current from all the finger lines. The specific metallic grid design shown in FIG. 3A can be used as a front or back contact of a PV structure. The placement of busbar 302 can be determined based whether the metallic grid 300 is used a front or back contact of a PV structure. For example, if used as a front metallic grid of a PV structure, busbar 302 can be placed on the right edge of a PV structure, and placed on the left edge of the structure if used as a back metallic contact of the bifacial PV structure.

FIG. 3B shows a cross-sectional view of the fabricated single edge busbar metallic grid attached to the fingerless bifacial photovoltaic cell forming front and back electrodes of the PV structure. The semiconductor multilayer structure shown in FIG. 3B includes finger lines (not shown) run from left to right, and the busbars run in and out of the paper. From FIG. 3B, the busbars on the front and the back surfaces of the bifacial PV structures are placed at the opposite edges of the PV structure. This configuration can further improve power gain because the busbar-induced shading now occurs at locations that were less effective in energy production. In general, the edge-busbar configuration can provide at least an approximate 2.1% power gain.

Note that the single busbar per surface configurations (either the center busbar or the edge busbar) not only can provide power gain, but also can reduce fabrication cost, because less metal will be needed for busing ribbons. Moreover, the metallic grid on the front sun-facing surface can include parallel metal lines (such as fingers), each having a cross-section with a curved parameter to ensure that incident sunlight on these metal lines is reflected onto the front surface of the photovoltaic cell, thus further reducing shading. Such a shade-free front electrode can be achieved by electroplating Ag- or Sn-coated Cu using a well-controlled, cost-effective patterning scheme.

Different techniques can be used in order to provide a good physical and ohmic contact between the fabricated metallic grid and the surface (e.g., TCO) of the gridless PV structure. One way to provide the proper physical contact between the fabricated grid and PV structure is to use coated metallic structures. These metallic structures may be in different forms and shapes and may include one or more metallic wires with various physical characteristics such as material, cross section, length, and width. For example, the metallic structures may include one or more copper (or some form of copper alloy) wires connected in different forms.

In some embodiments, the metallic structure of the fabricated metallic grid can be coated with a conductive low melting metal (e.g., Iridium) or alloy. This way, the coated metal or alloy can be melted with relatively low temperatures to provide the desired bond between the fabricated metallic grid and the gridless PV structure. In other embodiments, some form of adhesive compound (e.g., an adhesive polymer compound) may be used to attach the fabricated metallic grid to the gridless PV structure. The metallic structure (e.g., metallic wire) can be coated with a conductive adhesive blend such as a conductive film wrapped around the cross section of the metallic structure. This fabrication process can be performed while the photovoltaic module is laminated for more efficient manufacturing process.

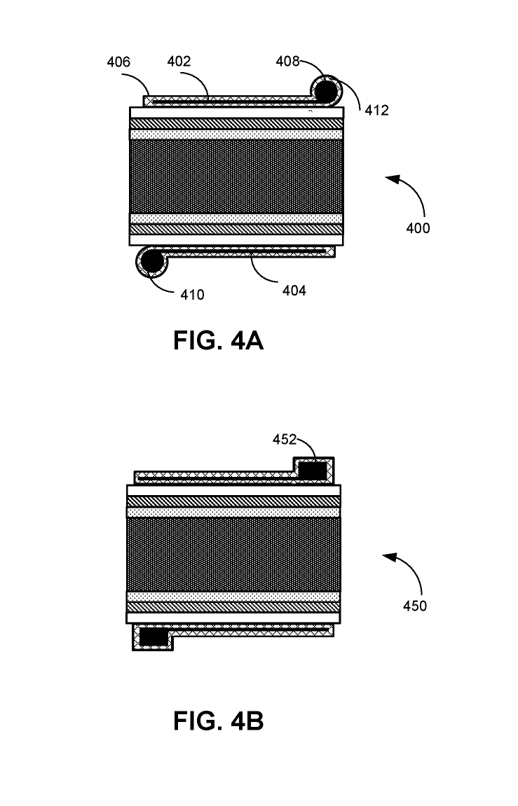

FIG. 4A shows a cross-sectional view of the adhesive coated single edge busbar metallic grid attached to the bifacial photovoltaic cell forming front and back electrodes of the PV structure, in accordance with an embodiment of the present invention. Semiconductor multilayer structure 400 shown in FIG. 4A includes a number of finger lines, for example finger line 402 and 404, (only cross section of one finger line on each surface is shown) having adhesive coatings, for example adhesive coating 406, and run horizontally, and busbars 408 and 410 that are wrapped with adhesive coating, for example adhesive coating 412, that run in and out of the paper. Similar to FIG. 3B, the adhesive coated busbars on the front and the back surfaces of the bifacial PV structures are placed at the opposite edges of the PV structure. This configuration not only improves power gain because the busbar-induced shading now occurs at locations that were less effective in energy production, but also provides an excellent physical and ohmic contact using the fabricated metallic grid with an adhesive coating.

As shown in FIG. 4A, the coated core of the fabricated metallic grid can be circular/ellipsoid shaped. However, the core of the fabricated metallic grid can have different shapes and forms. For example, a square/rectangle shaped core can be fabricated by dividing a metallic sheet in smaller portion to be used as the building blocks of the fabricated metallic grid. FIG. 4B shows a cross-sectional view of the adhesive coated single edge busbar metallic grid attached to the bifacial photovoltaic cell forming front and back electrodes of the PV structure. As can be seen, coated core of the metallic grid 452 is rectangle shaped which can potentially have slightly bigger surface area in contact with the gridless PV structure to further reduce the electric resistance of the metallic grid.

It is also possible to reduce the power-loss effect caused by the increased distance from the finger edges to the busbars by increasing the aspect ratio of the finger lines. For example, with gridlines with an aspect ratio of 0.5, the power loss could degrade from 3.6% to 7.5% as the gridline length increases from 30 mm to 100 mm. However, with a higher aspect ratio, such as 1.5, the power loss could degrade from 3.3% to 4.9% for the same increase of gridline length. In other words, using high-aspect ratio gridlines can further improve performance. Such high-aspect ratio gridlines can be achieved using an electroplating technique. Details about the shade-free electrodes with high-aspect ratio can be found in U.S. patent application Ser. No. 13/048,804 (Attorney Docket No. P54-1NUS), entitled “Solar Cell with a Shade-Free Front Electrode,” by inventors Zheng Xu, Jianming Fu, Jiunn Benjamin Heng, and Chentao Yu, filed 15 Mar. 2011, the disclosure of which is incorporated herein by reference in its entirety herein.

Using a high-aspect ratio gridlines along with separate fabrication of metallic grid can provide freedom to design different scheme of patterns that could yield to production of more efficient photovoltaic modules. For example, one or more intertwined metallic wires can be used to fabricate the metallic grid in form of a web or mesh. Metallic grid fabricated using this technique may come in several shapes and forms to accommodate different design criteria and specification needs. For example, width or dimeter of the metallic wire(s), spacing between the wires, number of wires used, and patterns of open spaces create using the network of intertwined wire(s) can be easily manipulated.

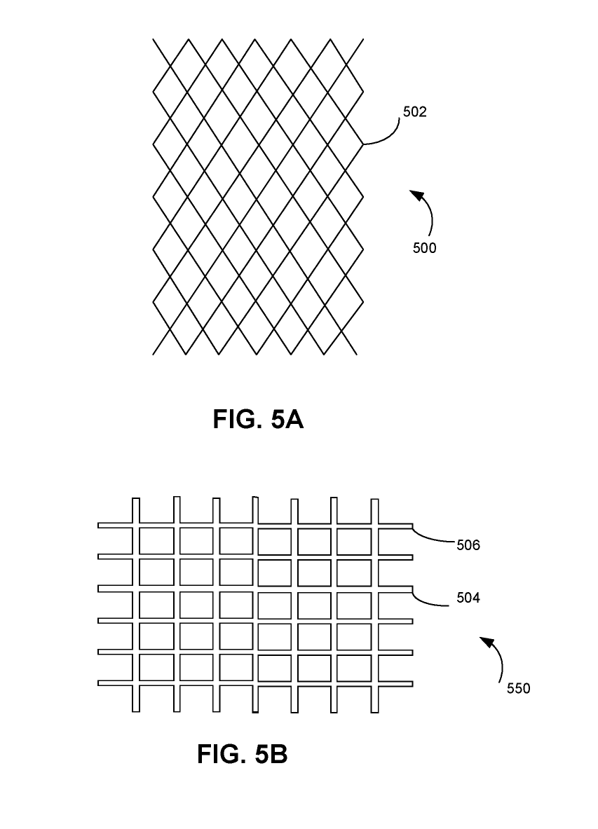

FIG. 5A shows an exemplary metallic grid that can be formed using the intertwined metallic wire, in accordance of an embodiment of the present invention. As shown in FIG. 5A, single metallic wire 502 can be used to form web 500 that has spaces in shape of trapezoid to cover PV structures. The thickness of the metallic wire can be from a few microns to a few hundred microns depending on design specifications. One factor in determining the width of the metallic wire can be its aspect ratio. Having a high-aspect ratio metallic grid can allow the metallic wire to be really thin so that shading losses can be minimized. In addition, the electrical resistance of such grids can typically be lower than conventional grids since the interconnection nature of the web created allows several current flow paths in compare with conventional grids.

FIG. 5B shows another exemplary metallic grid that can be formed using interconnected metallic wires, in accordance with an embodiment of the present invention. As shown in FIG. 5B, metallic wires (for example, metallic wire 504 and 506) can be used to form flat mesh 550 that has spaces in shape of square to cover some portion of PV structures. The metallic wires can be connected to each other without being weaved so that the desired aspect ratio of the mesh can be easily implemented. In addition, the density of metallic wires covering area can be balanced so that maximum area of PV structures can be covered for effective current collection while minimize shading losses associated with opaque electrodes of PV structures. Note that metallic wires shown in FIG. 5B scaled so that the connection can be visible. The thickness of metallic wires can be comparable to metallic wire(s) of FIG. 5A, which can range from a few microns to few hundred microns.

Bifacial Photovoltaic Panels Based on Strips with Shared Metallic Grid

Multiple gridless photovoltaic cells can be assembled to form a photovoltaic module or panel via a typical panel fabrication process, where having gridless bifacial PV structures can be advantageous. In conventional photovoltaic module fabrications, the single- or double-busbar photovoltaic cells are strung together using stringing ribbon(s) (also called tabbing ribbon(s)), which are soldered onto the busbars. More specifically, the stringing ribbon(s) weave from the front surface of one cell to the back surface of the adjacent cell to connect the cells in series. For gridless bifacial PV structures, multiple cells can be connected with one another and/or stacked to form a string using a shared metallic grid.

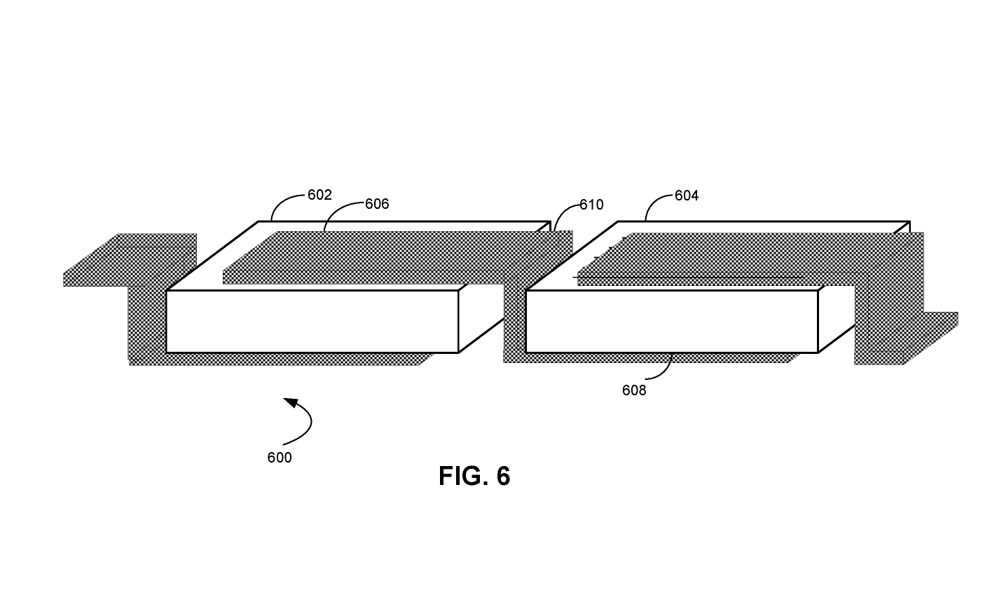

FIG. 6 shows a serial connection of two adjacent photovoltaic structures sharing a single metallic grid formed from a network of metallic wires, in accordance with an embodiment of the present invention. The shared metallic grid not only can collects and directs the generated current from the PV structures, but also can be used to make the inter-connection of the adjacent photovoltaic cell. The shared metallic grid includes multiple portions. As shown in FIG. 6, first portion 606 of the shared metallic grid is attached to the front surface of photovoltaic cell 602 and second portion 608 of the shared metallic grid is attached to the back surface of the photovoltaic cell 604, thus connection the photovoltaic cells 602 and 604 in series. Third portion 610 of the shared metallic grid can connect first portion 606 and second portion 608. As can be seen in FIG. 6, third portion 610 of the shared metallic grid can be bent or have joints in one or more places, typically using sufficient amount of heat and pressure, in one or more locations in order to provide the series connection of photovoltaic cells 602 and 604.

In some embodiments, multiple photovoltaic structures can be connected using the same topology to form an electrically integrated string of interconnected photovoltaic structure. In some embodiments, the bend angel(s) and length of third portion 610 connecting two adjacent PV cells is determined by the packing density or the distance between adjacent photovoltaic cells, and can be quite short, for example between 3 and 12 mm. This geometric configuration (shorter length) ensures that the shared metallic grid has a very low overall series resistance.

Note that the shared mesh configuration of metallic grid works well with metallic grid going from the front edge of one photovoltaic cell to the back edge of an adjacent photovoltaic cell, when the front-side metallization for all the cells are of the same polarity and the back-side electrodes for all the cells are all of opposite polarity. Note that each metallized side can be an electron- or hole-collecting side depending on photovoltaic design and fabrication process. For example, front-side of photovoltaic cells can be an electron-collecting side while the back-side would be a hole-collecting side of the photovoltaic structures.

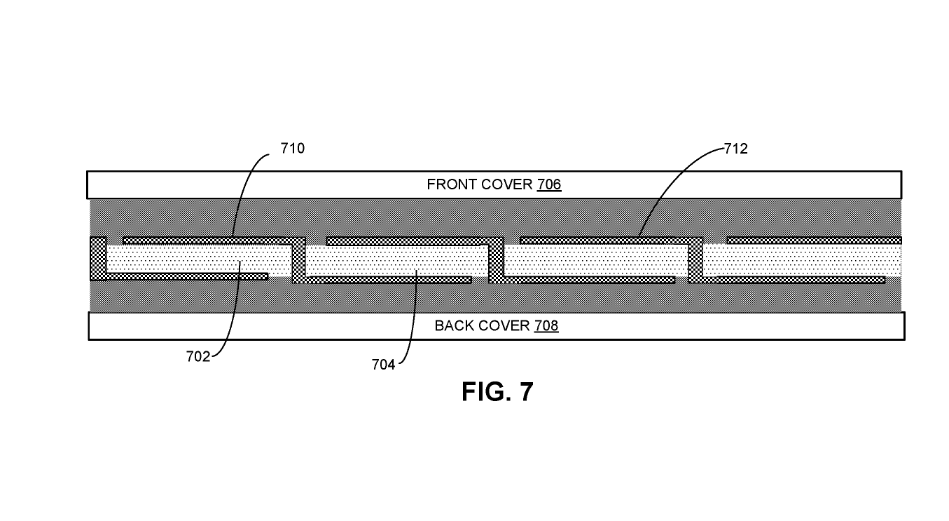

Multiple photovoltaic cells can be coupled this way to form a string, and multiple strings can be coupled electrically in series or in parallel. FIG. 7 shows a cross-sectional view of a string of gridless photovoltaic cells connected via shared metallic grids, in accordance with an embodiment of the present invention. In FIG. 7, a string of photovoltaic cells (such as cells 702 and 704) are sandwiched between a front glass cover 706 and a back cover 708. More specifically, the photovoltaic cells are arranged in such a way that allows the front-side metallization of all the cells to be of one polarity and their back-side metallization to be of the other polarity. The shared metallic grids, such as grids 712 and 714, serially couple adjacent photovoltaic cells by coupling together the front-side metallization of a photovoltaic cell and the back-side metallization of its adjacent photovoltaic cell.

In some embodiments, the shared metallic grid can be attached the to gridless PV structure concurrently with a lamination process, during which the edge-overlapped photovoltaic cells are placed in between a front-side cover and a back-side cover along with appropriate sealant material, which can include adhesive polymer, such as ethylene vinyl acetate (EVA). During lamination, heat and pressure are applied to cure the sealant, sealing the photovoltaic cells between the front-side and back-side covers. The same heat and pressure can result in the shared metallic grid to bond and form the string shown in FIG. 7. Also note that because the photovoltaic cells are five-inch or six-inch Si wafers that are relatively flexible, the pressure used during the lamination process can be relatively large without the worry that the cells may crack under such pressure. In some embodiments, the pressure applied during lamination process can be above 1.0 atmospheres, such as 1.2 atmospheres

Bifacial Panels Based on Cascaded Strips with Shared Metallic Grid

Generally, a portion of the generated power by photovoltaic cells is consumed by the serial internal resistance in the photovoltaic cells themselves. That means the less the total internal resistance the entire panel has, the less power is consumed by the photovoltaic cells themselves, and the more power is extracted to the external load. One way to reduce the power consumed by the photovoltaic cells is to reduce the total internal resistance. Various approaches can be used to reduce the series resistance of the electrodes at the cell level.

On the panel level, one effective way to reduce the total series resistance is to connect a number of cells in parallel, instead of connecting all the cells within a panel in series. As a result, the total internal resistance of the photovoltaic panel is much smaller than the resistance of each individual photovoltaic cell. However, the output voltage V_{load} is now limited by the open circuit voltage of a single photovoltaic cell, which is difficult in a practical setting to drive load, although the output current can be n times the current generated by a single photovoltaic cell.

In order to attain an output voltage that is higher than that of the open circuit voltage of a single cell while reducing the total internal resistance for the panel a subset of photovoltaic cells can be connected into a string, and the multiple strings can be connected in parallel. Parallelly connecting the strings also means that the output voltage of the panel is now the same as the voltage across each string, which is a fraction of the output voltage of a photovoltaic panel with all cells connected in series. Because the output voltage of each string is determined by the voltage across each photovoltaic cell (which is often slightly less than V_{oc}) and the number of serially connected cells in the string, one can increase the string output voltage by including more cells in each string. However, simply adding more cells in each row will result in an enlarged panel size, which is often limited due to various mechanical factors. Note that the voltage across each cell is mostly determined by V_{oc}, which is independent of the cell size. Hence, it is possible to increase the output voltage of each string by dividing each standard sized (5- or 6-inch) photovoltaic cell into multiple serially connected smaller cells (i.e., strips). As a result, the output voltage of each string of photovoltaic cells is increased multiple times.

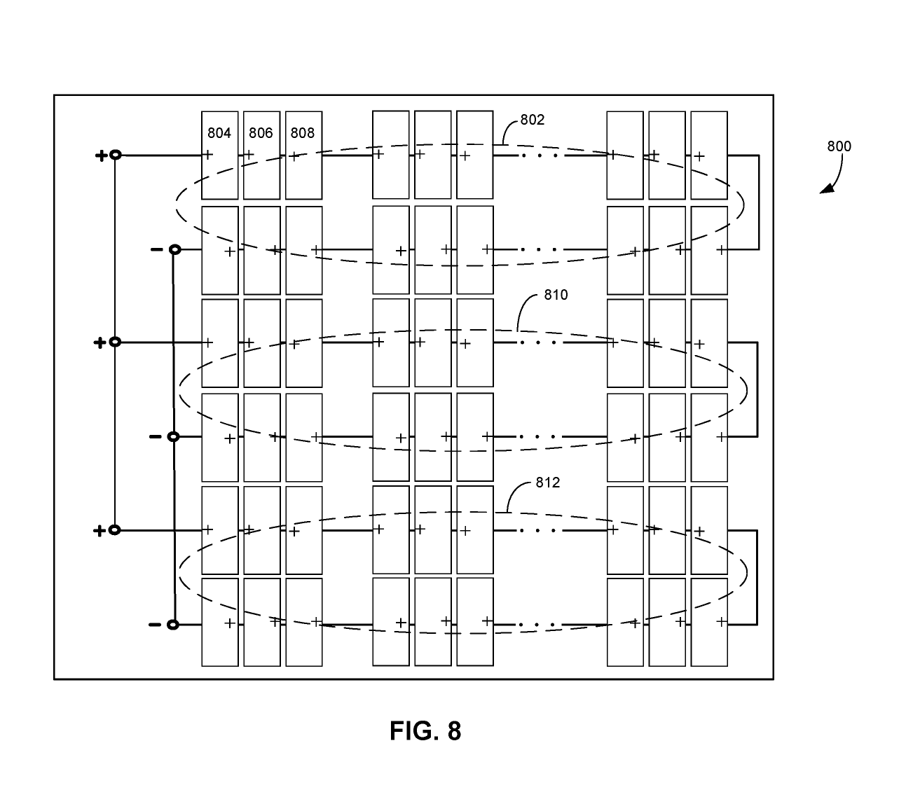

FIG. 8 shows an exemplary photovoltaic panel 800 includes arrays of photovoltaic cells that are arranged in a repeated pattern, such as a matrix that includes a plurality of rows. In some embodiments, photovoltaic panel 800 can include six rows of inter-connected smaller cells, with each row including 36 smaller cells. Note that each smaller cell is approximately ⅓ of a 6-inch standardized photovoltaic cell. For example, smaller cells 804, 806, and 808 are evenly divided portions of a standard-sized cell. Photovoltaic panel 800 is configured in such a way that every two adjacent rows of smaller cells are connected in series, forming three U-shaped strings. In FIG. 8, the top two rows of smaller cells are connected in series to form a photovoltaic string 802, the middle two rows of smaller cells are connected in series to form a photovoltaic string 810, and the bottom two rows of smaller cells are connected in series to form a photovoltaic string 812.

In the example shown in FIG. 8, photovoltaic panel 800 can include three U-shaped strings with each string including 72 smaller cells. The V_{oc} and I_{sc} of the string are 72V_{oc}_{_}_{cell} and I_{sc}_{_}_{cell}/3, respectively; and the V_{oc} and I_{sc} of the panel are 72V_{oc}_{_}_{cell}, and I_{sc}_{_}_{cell}, respectively. Such panel level V_{oc} and I_{sc} are similar to those of a conventional photovoltaic panel of the same size with all its 72 cells connected in series, making it possible to adopt the same circuit equipment developed for the conventional panels. Furthermore, the total internal resistance of panel 900 is significantly reduced. Assume that the internal resistance of a conventional cell is R_{cell}. The internal resistance of a smaller cell is Rₛₘₐₗₗ_{_}_{cell}=R_{cell}/3. In a conventional panel with 72 conventional cells connected in series, the total internal resistance is 72R_{cell}. In panel 800 as illustrated in FIG. 8, each string has a total internal resistance R_{string}=72 Rₛₘₐₗₗ_{_}_{cell}=24 R_{cell}. Since panel 900 has 3 U-shaped strings connected in parallel, the total internal resistance for panel 900 is R_{string}/3=8 R_{cell}, which is 1/9 of the total internal resistance of a conventional panel. As a result, the amount of power that can be extracted to external load can be significantly increased.

As one can see, the greater the number of strips from each PV cell is, the lower the total internal resistance of the panel can be, and the more power one can extract from the panel. However, a tradeoff is that as the number of strips from each PV cell increases, the number of connections required to inter-connect the strings also increases, which can increase the amount of contact resistance. Also, the greater the number of strips from each PV cells, the more strips a single cell may need to be divided into, which may increase the associated production cost and decrease overall reliability due to the larger number of strips used in a single panel.

Another consideration in determining the number of strips from each PV cell is the contact resistance between the electrode and the photovoltaic structure on which the electrode is formed. The greater this contact resistance is, the greater the number of strips made from each PV cell might need to be to reduce effectively the panel's overall internal resistance. Hence, for a particular type of electrode, different number of strips for each PV cell might be needed to attain sufficient benefit in reduced total panel internal resistance to offset the increased production cost and reduced reliability. For example, conventional silver-paste or aluminum based electrode may require the number of strips from each PV cell to be greater than 4 for each cell within each string, because the process of screen printing and annealing silver paste on a cell does not produce ideal resistance between the electrode and underlying photovoltaic structure.

In some embodiments, the serial connection between adjacent photovoltaic cells is achieved by partially overlapping the adjacent PV cells, thus resulting in a planar metallic grid that can be shared with the adjacent PV structures. This way, as number of strip from dividing each photovoltaic cell increases, the number of connections required to inter-connect the strings does not necessarily increase contact resistance as the metallic grid between the adjacent photovoltaic cells is being shared. In addition, easier fabrication of electroplated metallic grids in isolation can be beneficial while determining the number strips formed from each photovoltaic cell by effectively reducing the contact resistance between the electrode and the photovoltaic structure on which the electrode is formed.

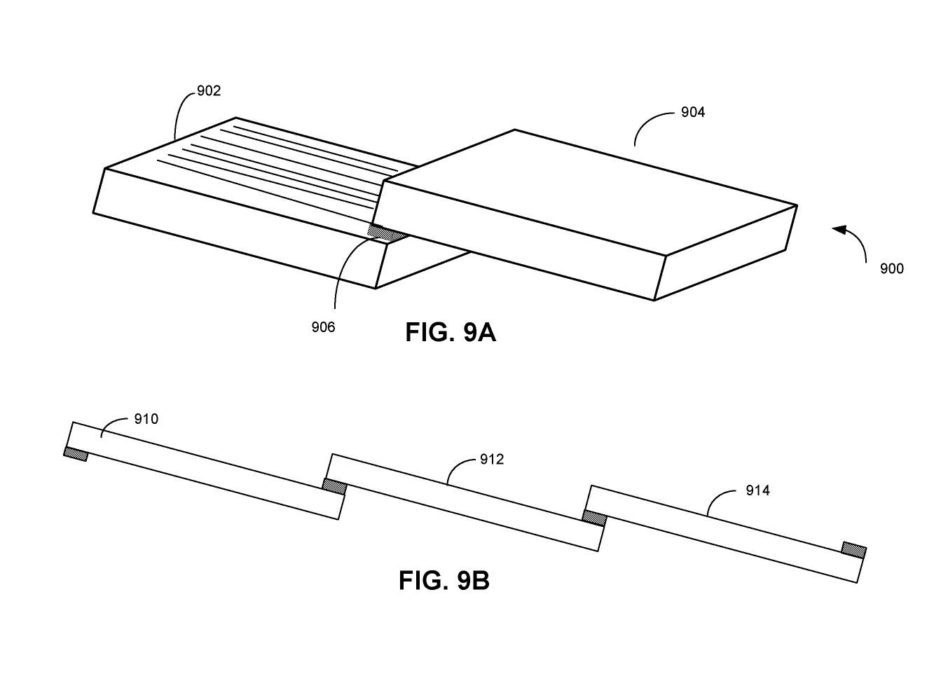

FIG. 9A shows a detailed view of an exemplary serial connection between two adjacent PV cells with a shared metallic grid having a single edge busbar per surface, in accordance with some embodiments of the present invention. In FIG. 9A, gridless photovoltaic cells 902 and 904 are coupled to each other via a shared metallic grid having a single edge busbar 906 located at the top surface of cell 902 and the bottom surface of PV cell 904. More specifically, the bottom surface of cell 904 partially overlaps with the top surface of photovoltaic cell 902 at the edge in such a way that edge busbar 906 concurrently has direct contact with top surface of PV cell 902 and bottom surface of PV cell 904. In other words, using a shared metallic grid allows current collection from two adjacent gridless PV cells with only a single busbar.

FIG. 9B shows a side-view of an exemplary string of adjacent edge-overlapped gridless PV cells having a shared metallic grid with a single edge busbar, in accordance with an embodiment of the current invention. In FIG. 9B, Gridless PV cell 910 partially overlaps adjacent cell 912, which also partially overlaps (on its opposite end) photovoltaic cell 914. Such a string of photovoltaic cells forms a pattern that is similar to roof shingles. The overlapping should be kept to a minimum to minimize shading caused by the overlapping. The same shingle pattern can extend along all fingerless photovoltaic cells in a row using a shared metallic grid having a single busbar for adjacent photovoltaic cells. To ensure that PV cells in two adjacent rows are connected in series, the two adjacent rows need to have opposite shingle patterns, such as right-side on top for one row and left-side on top for the adjacent row. Moreover, a metal tab can be used to serially connect the end cells at the two adjacent rows. Detailed descriptions of serially connecting solar cells in a shingled pattern can be found in U.S. patent application Ser. No. 14/510,008 (Attorney Docket No. P67-3NUS), entitled “MODULE FABRICATION OF SOLAR CELLS WITH LOW RESISTIVITY ELECTRODES,” by inventors Jiunn Benjamin Heng, Jianming Fu, Zheng Xu, and Bobby Yang and filed 8 Oct. 2014, the disclosure of which is incorporated herein by reference in its entirety herein.

Note that although the examples above illustrate adjacent photovoltaic cells being physically coupled with a single-busbar configuration, in some embodiments of the present invention, the adjacent photovoltaic cells can also be coupled using a shared metallic grid without any busbars. As discussed previously, having the shared metallic grid fabricated separately can give more freedom to choose from different viable metallization pattern schemes connecting the fingerless PV structures. Although there may be different possible pattern schemes for the shared metallic grid, all these schemes provide a continuous coverage between adjacent PV structures sharing the metallic grid.

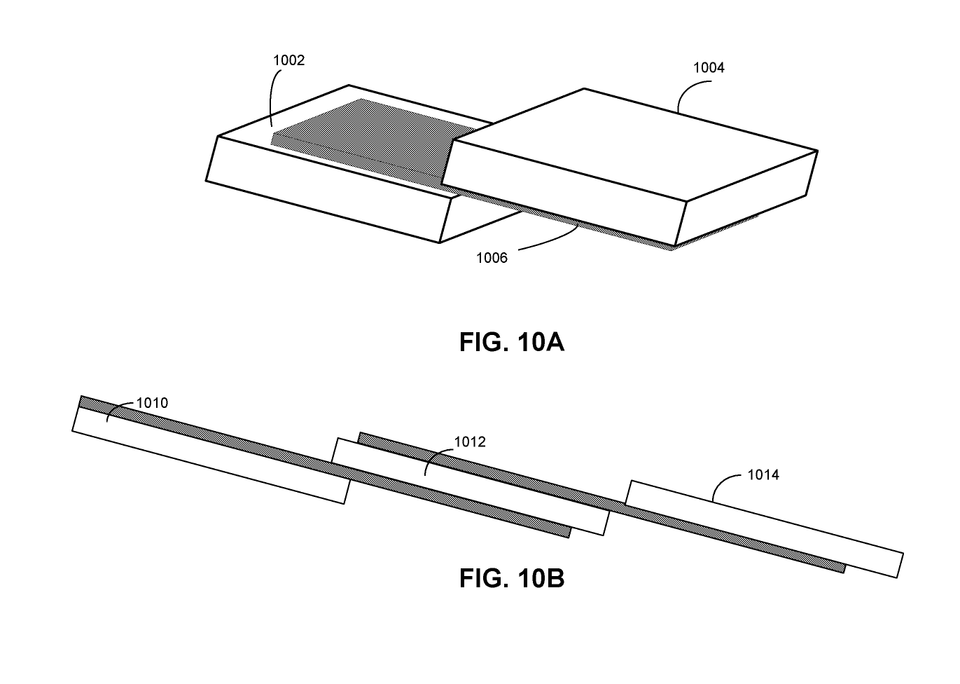

FIG. 10A a detailed view of an exemplary serial connection between adjacent photovoltaic cells with a shared metallic grid in form of a mesh, in accordance with some embodiments of the present invention. In FIG. 10A, gridless photovoltaic cells 1002 and 1004 are coupled to each other via a shared metallic grid with network of wires 1006 located between the top surface of cell 1002 and the bottom surface of PV cell 1004. More specifically, network of wires 1006 can cover a portion of the bottom surface of cell 1004 and extend over to concurrently cover a portion of the top surface of photovoltaic cell 1002.

One factor in the metallic grid design having a web pattern is the balance between the increased resistive losses associated with thickness of wires within the web of wires and the increased reflection and shading effect caused by high density of metallic coverage of the surface area the web of wires covers. In some embodiments, to prevent power loss due to series resistance while minimizing the shading effect, metallic wire(s) can have substantially similar thickness of finger lines used in a standard two-busbar metallization configuration of conventional PV cells.

FIG. 10B shows a side-view of an exemplary string of adjacent edge-overlapped gridless PV cells having a shared metallic grid in form of a mesh, in accordance with an embodiment of the current invention. In FIG. 10B, Gridless PV cell 1010 partially overlaps adjacent cell 1012, which also partially overlaps (on its opposite end) photovoltaic cell 1014. The overlapping should be kept to a minimum to minimize shading caused by the overlapping. The same shingle pattern can extend along all fingerless photovoltaic cells in a row using a shared metallic grid having a single busbar for adjacent photovoltaic cells.

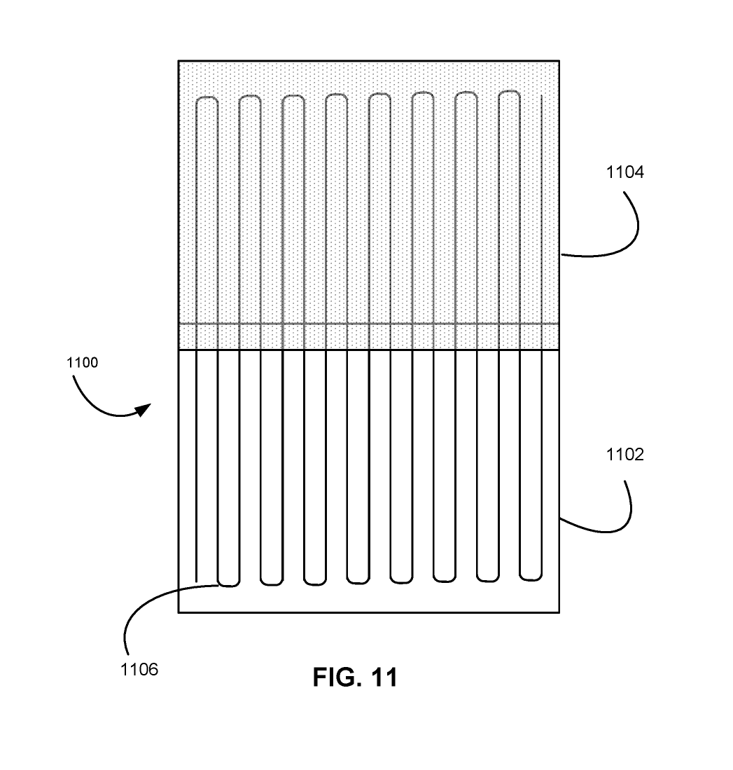

FIG. 11 shows an exemplary serial connection between two adjacent photovoltaic cells with a shared metallic grid having a serpentine pattern, according to one embodiment of the present invention. To enable cascaded and bifacial operation using a shared metallic grid, the grid pattern may be continuous and formed from one PV cell and extend through the adjacent PV structure. In the example shown in FIG. 11, shared metallic grid 1106 can include a single continuous metallic wire that may be in form of a serpentine pattern to connect two adjacent PV structure 1102 and 1104. Specifically, the continuous metallic wire pattern can include several substantially parallel segments covering a portion of a fingerless photovoltaic cell surface and extend over to cover a portion of an adjacent PV cell's surface. Further, the end portion of these substantially parallel segments can be connected to the neighboring end portion of other parallel segment in a substantially loop-shaped pattern. In some embodiments, the width of the continuous wire, such as wire 1106, can be larger than a typical finger line and smaller than a typical busbar width of a conventional metallic grid. For example, the width of the continuous wire can be between a few microns to a few hundred microns while the spacing between the substantially parallel segments can be from a few hundred microns to a few millimeters.

### Exemplary Fabrication Method

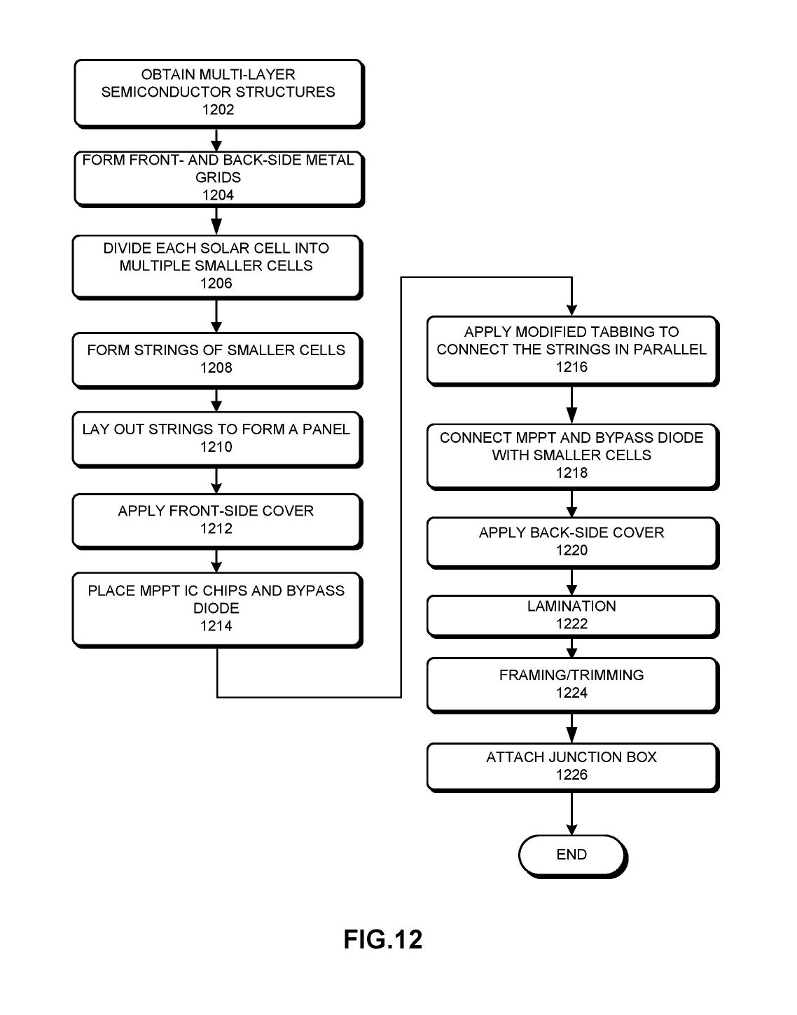

FIG. 12 shows a flow chart of the fabrication process of a photovoltaic panel, in accordance with an embodiment of the present invention. During fabrication, conventional solar cells comprising multi-layer semiconductor structures are first fabricated using conventional wafers (operation 1202). In some embodiments, the multi-layer semiconductor structure can include a double-sided tunneling heterojunction photovoltaic cell. The photovoltaic cells can have a standard size, such as the standard 5-inch or 6-inch squares. In some embodiments, the photovoltaic cells are 6×6 inch square-shaped cells. Subsequently, front- and back-side metallic grids are fabricated in isolation. In contrast with conventional fabrication method that the front- and back-side metallic grids are deposited on the front and back surfaces of the photovoltaic cells respectively to complete the bifacial photovoltaic cell fabrication, the metallic grids are processed and later attached to the gridless photovoltaic structure (operation 1204). In some embodiments, fabricating the front- and back-side metallic grids may include electroplating of a Cu grid, which is subsequently coated with Ag or Sn. Different types of metallic grids can be formed, including, but not limited to: a metallic grid with a single busbar at the center and a metallic grid with a single busbar at the cell edge. Note that for the edge-busbar configuration, the busbars at the front and back surfaces of the photovoltaic cells are placed at opposite edges, respectively.

Subsequent to fabrication of the front and back metallic grids, each photovoltaic cell is divided into multiple smaller cells (operation 1206). Various techniques can be used to divide the cells. In some embodiments, a laser-based scribe-and-cleave technique is used. More specifically, a high-power laser beam is used to scribe the surface of the photovoltaic cell at the desired locations to a pre-determined depth (such as 20% of the total stack thickness), followed by applying appropriate force to cleave the scribed photovoltaic cell into multiple smaller cells. Note that, in order to prevent damage to the emitter junction, it is desirable to apply the laser scribing at the photovoltaic cell surface corresponding to the surface field layer. For example, if the emitter junction is at the front surface of the photovoltaic cell, the laser scribing should be applied to the back surface of the photovoltaic cell.

After the formation of the smaller cells, a number of smaller cells are connected together in series to form a photovoltaic cell string (operation 1208). In some embodiments, two rows of smaller cells with each row including 32 smaller cells are connected in series to form a U-shaped string. Note that, depending on the busbar configuration, the conventional stringing process may need to be modified. In some embodiments, the serial connection between adjacent smaller cells is achieved by partially overlapping the adjacent smaller cells, thus resulting in the direct contact of the corresponding edge busbars. FIG. 9A presents a diagram illustrating the serial connection between two adjacent smaller cells with a single edge busbar per surface, in accordance with an embodiment of the present invention. In FIG. 9A, smaller cell 902 and smaller cell 904 are coupled to each other via an edge busbar 906 located at the top and bottom surfaces of smaller cells 902 and 904.

Subsequent to the formation of multiple strings of smaller cells, the multiple photovoltaic strings are laid out next to each other to form a panel (operation 1210). In some embodiments, three U-shaped strings are laid out next to each other to form a panel that includes 6 rows of smaller cells. After laying out the strings, the front-side cover is applied (operation 1212). In some embodiments, the front-side cover is made of glass.

For photovoltaic modules implementing cell-level MPPT or cell-level bypass protection, the MPPT IC chips and bypass diode can be placed at appropriate locations, including, but not limited to: corner spacing between photovoltaic cells, and locations between adjacent photovoltaic cells (operation 1214). In some embodiments, the MPPT IC chips and bypass diode may be implemented at a multi-cell level or string level. In some embodiments, each row of smaller cells may be coupled to an MPPT IC and/or a bypass diode.

The U-shaped strings are then connected to each other via a modified tabbing process (operation 1216). More specifically, the strings are connected to each other in parallel with their positive electrodes coupled together to form the positive output of the panel and negative electrodes coupled together to form the negative output of the panel. Electrical connections between the MPPT IC chips and bypass diodes and the corresponding smaller cell electrodes are formed to achieve a completely interconnected photovoltaic panel (operation 1218). Subsequently, the back-side cover is applied (operation 1220), and the entire photovoltaic panel can go through the normal lamination process, which would seal the cells, the MPPT ICs, and the bypass diode in place (operation 1222). Note that to ensure superior bifacial performance, the backside cover is also made of glass. The lamination process is then followed by framing and trimming (operation 1224), and the attachment of a junction box (operation 1226).

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

The methods and processes described in the detailed description section can be embodied as code and/or data, which can be stored in a computer-readable storage medium as described above. When a computer system reads and executes the code and/or data stored on the computer-readable storage medium, the computer system can perform the methods and processes embodied as data structures and code and stored within the computer-readable storage medium.

The foregoing descriptions of embodiments of the invention have been presented for purposes of illustration and description only. They are not intended to be exhaustive or to limit the invention to the forms disclosed. Accordingly, many modifications and variations may be apparent to practitioners skilled in the art. Additionally, the above disclosure is not intended to limit the invention. The scope of the invention is defined by the appended claims.

What is claimed is:

1. A photovoltaic module comprising:
a first photovoltaic structure;
a second photovoltaic structure; and
at least one common, continuous, and conductive grid;
wherein a hole-collection side of the first photovoltaic structure is coupled to a first side of the conductive grid; and
wherein an electron-collection side of the second photovoltaic structure is coupled to a second side of the conductive grid.

2. The photovoltaic module of claim 1, wherein at least one of the first and second photovoltaic structures is a double-sided tunneling heterojunction photovoltaic structure, which includes:
a base layer;
first and second quantum tunneling barrier (QTB) layers deposited on both surfaces of the base layer;
an amorphous silicon emitter layer; and
an amorphous silicon surface field layer;
wherein the photovoltaic structure can absorb light from both surfaces.

3. The photovoltaic module of claim 1, wherein at least one of the first or second photovoltaic structures does not include an electrode.

4. The photovoltaic module of claim 1, wherein a plurality of photovoltaic structures arranged into a plurality of subsets;
wherein photovoltaic structures in a respective subset are electrically coupled in series;
wherein the subsets of photovoltaic structures are electrically coupled in parallel; and
wherein a number of photovoltaic structures in each subset is sufficiently large such that an output voltage of the photovoltaic module is substantially the same as an output voltage of a conventional photovoltaic module with all of its substantially square shaped photovoltaic structures coupled in series.

5. The photovoltaic module of claim 1, wherein the conductive grid includes one or more interconnected metallic wires forming a flat mesh having openings in shape of a polygon.

6. The photovoltaic module of claim 1, wherein the conductive grid includes one or more intertwined metallic wires forming a mesh having openings in shape of a polygon.

7. The photovoltaic module of claim 1, wherein the conductive grid includes at least one metallic wire formed with multiple parallel segments, wherein each end of a respective parallel segment is connected to at least one end of an adjacent parallel section.

8. The photovoltaic module of claim 1, wherein the conductive grid comprises a busbar and a number of finger lines connected to the busbar, and wherein the busbar is coupled to at least one surface of each photovoltaic structure sharing the conductive grid.

9. The photovoltaic module of claim 8, wherein the first and second photovoltaic structures are positioned such that the busbar is connected to a first edge of the first photovoltaic structure and a second edge of the second photovoltaic structure partially overlapped on the first edge, thereby facilitating a serial connection between the two adjacent photovoltaic structures and eliminating uncovered space there between.

10. The photovoltaic module of claim 1, wherein the conductive grid is coated with at least one of heat-activated and pressure-activated adhesive materials for bonding with one or more surfaces of photovoltaic structures sharing the metallic grid.

11. The photovoltaic module of claim 1, wherein the conductive grid is coated with low melting conductive alloy for bonding with one or more surfaces of photovoltaic structures sharing the metallic grid.

12. A method for fabricating a photovoltaic module comprising:
obtaining a plurality of gridless photovoltaic structures;
obtaining a plurality of continuous and conductive grids;
electrically coupling each pair of the gridless photovoltaic structures in series using a respective continuous and conductive grid to form a string;
electrically coupling multiple strings to form the photovoltaic module; and
applying a frond-side cover and a back side cover over the multiple electrically coupled strings.

13. The method of claim 12, wherein at least one conductive grid comprises a busbar and a number of finger lines connected to the busbar, and wherein the busbar is coupled to at least one surface of each photovoltaic structure sharing the conductive grid.

14. The method of claim 13, wherein two adjacent photovoltaic structures in a respective string are positioned such that the busbar is connected to a first edge of a respective photovoltaic structure and a second edge of an adjacent photovoltaic structure partially overlapped on the first edge, thereby facilitating a serial connection between the two adjacent photovoltaic structures and eliminating uncovered space there between.

15. The method of claim 12, wherein conductive grid includes one or more intertwined metallic wires forming a mesh having openings in shape of a polygon.

16. The method of claim 12, wherein the conductive grid includes one or more interconnected metallic wires forming a flat mesh having openings in shape of a polygon.

17. The method of claim 12 further comprising:
dividing the plurality of gridless photovoltaic structures into m smaller photovoltaic structures; and
arranging all the smaller photovoltaic structures in the module into m strings, which are coupled together in parallel.

18. The method of claim 17, wherein the respective grid includes at least one metallic wire covering a portion of a first smaller photovoltaic surface and extend through a second smaller photovoltaic surface, thereby electrically connecting two adjacent photovoltaic structures.

19. The method of claim 12, wherein the respective grid is coated with at least one of heat-activated and pressure-activated adhesive materials for bonding with one or more surfaces of smaller photovoltaic structures sharing the conductive grid.

20. The method of claim 12, wherein the respective grid is coated with low melting conductive alloy for bonding with one or more surfaces of smaller photovoltaic structures sharing the conductive grid.
